(19) United States
(12) Patent Application Publication
(10) Pub. No.: US 2026/0256020 A1
(43) Pub. Date: Aug. 27, 2026

(54) FLIP CHIP PACKAGE WITH HIGH PERFORMANCE MOLD COMPOUND

(71) Applicant: Texas Instruments Incorporated, Dallas, TX (US)

(72) Inventor: Enis Tuncer, Dallas, TX (US)

(21) Appl. No.: 19/062,170

(22) Filed: Feb. 25, 2025

(51) Int. Cl. H01L 23/00; H01L 23/29; H01L 23/31; H01L 23/498

(52) U.S. Cl. CPC H10W 74/473; H10W 70/635; H10W 74/121; H10W 72/072; H10W 72/241; H10W 72/248; H10W 90/724

(57) ABSTRACT

A semiconductor package comprises a semiconductor die. The semiconductor die comprises a first metal pad and a second metal pad. The first metal pad is separated from the second metal pad by a first distance. The semiconductor package also comprises a first bump structure coupled to the first metal pad. The semiconductor package also comprises a second bump structure coupled to the second metal pad. The first bump structure is separated from the second bump structure by a second distance. The first distance is smaller than the second distance. The semiconductor package also comprises a substrate. The substrate comprises a first trace coupled to the first bump structure and a second trace coupled to the second bump structure. The semiconductor package further comprises a mold compound covering the semiconductor die, the first bump structure, the second bump structure, and the substrate. The semiconductor package is suitable for applications adopting high performance mold compounds.

### FIELD

The present disclosure relates generally to flip chip packages, and more particularly to flip chip packages employing high performance mold compound for various applications.

### BACKGROUND

Processes for providing packaged semiconductor devices include mounting electronic devices to a package substrate, and covering the electronic devices with a mold compound to form packages. When the electronic devices are mounted on package substrates in flip chip packages, a solder material is used to couple post connects extending from metal pads on a device side surface of a semiconductor die to metal pads or traces on the package substrate. In a flip chip package, the semiconductor die is mounted with the device side surface facing the package substrate. A solder joint formed by the solder material mechanically attaches and electrically couples the semiconductor die to the package substrate.

The mold compound covering the electronic devices protects them from outside environment. The mold compound is usually formulated from epoxy resins containing inorganic fillers, catalysts, flame retardants, stress modifiers, adhesion promoters, and other additives. Mold compounds containing functional additives are usually considered as high performance mold compounds. For example, high performance mold compounds may contain magnetic fillers, such as iron, to improve inductor performance for power circuits or high performance mold compounds may contain thermally conductive fillers, such as aluminum oxide and boron oxide, to improve heat dissipation of the package.

### SUMMARY

This summary is provided to introduce a selection of disclosed concepts in a simplified form that are further described below in the detailed description including the drawings provided. This summary is not intended to limit the scope of the claimed subject matter.

Disclosed aspects include a semiconductor package. The semiconductor package comprises a semiconductor die. The semiconductor die comprises a first metal pad and a second metal pad. The first metal pad and the second metal pad are separated by a first distance. The semiconductor package also comprises a first bump structure coupled to the first metal pad. The semiconductor package also comprises a second bump structure coupled to the second metal pad. The first bump structure and the second bump structure are separated by a second distance. The first distance is smaller than the second distance. The semiconductor package also comprises a substrate. The substrate comprises a first trace coupled to the first bump structure and a second trace coupled to the second bump structure. The semiconductor package further comprises a mold compound covering the semiconductor die, the first bump structure, the second bump structure, and the substrate.

Disclosed aspects include a method of forming a semiconductor package. The method comprises providing a semiconductor die. The semiconductor die comprises a first metal pad and a second metal pad. The first metal pad and the second metal pad are separated by a first distance. The method also comprises forming a first bump structure coupled to the first metal pad. The method also comprises forming a second bump structure coupled to the second metal pad. The first bump structure and the second bump structure are separated by a second distance. The first distance is smaller than the second distance. The method also comprises coupling a substrate to the first bump structure and the second bump structure. The substrate comprises a first trace coupled to the first bump structure and a second trace coupled to the second bump structure. The method further comprises covering the semiconductor die, the first bump structure, the second bump structure, and the substrate with a mold compound.

Disclosed aspects include a device. The device comprises a printed circuit board (PCB). The device further comprises a semiconductor package on the PCB. The semiconductor package comprises a semiconductor die. The semiconductor die comprises a first metal pad and a second metal pad. The first metal pad and the second metal pad are separated by a first distance. The semiconductor package also comprises a first bump structure coupled to the first metal pad. The semiconductor package also comprises a second bump structure coupled to the second metal pad. The first bump structure and the second bump structure are separated by a second distance. The first distance is smaller than the second distance. The semiconductor package also comprises a substrate. The substrate comprises a first trace coupled to the first bump structure and a second trace coupled to the second bump structure. The semiconductor package further comprises a mold compound covering the semiconductor die, the first bump structure, the second bump structure, and the substrate.

### BRIEF DESCRIPTION OF THE DRAWINGS

Reference will now be made to the accompanying drawings, which are not necessarily drawn to scale, wherein:

FIG. 1A is a 3D view of an example semiconductor package designed to reduce electric field in high performance mold compound in accordance with certain aspects of present disclosure;

FIG. 1B is a cross-section view of the example semiconductor package of FIG. 1A along reference line 1B-1B;

FIG. 2A is a 3D view of another example semiconductor package designed to reduce electric field in high performance mold compound in accordance with certain aspects of present disclosure;

FIG. 2B is a cross-section view of the example semiconductor package of FIG. 2A along reference line 2B-2B;

FIG. 3 illustrates a fabrication process for an example semiconductor package designed to reduce electric field in high performance mold compound in accordance with certain aspects of present disclosure;

FIG. 4 a 3D view of an example device including a semiconductor package designed to reduce electric field in high performance mold compound in accordance with certain aspects of present disclosure;

FIG. 5 illustrates simulation results of electric field in mold compound for different semiconductor package designs.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including,” “includes,” “having,” “has,” “with,” or variants thereof are intended to be inclusive in a manner similar to the term “comprising,” and thus should be interpreted to mean “including, but not limited to.”

Unless otherwise stated, “about,” “approximately,” or “substantially” preceding a value means+/−10 percent of the stated value. One or more structures, features, aspects, components, etc., may be referred to herein as first, second, third, etc., such as first and second terminals, first, second, and third dies, etc., for ease of description in connection with a particular drawing, where such are not to be construed as limiting with respect to the claims. Various disclosed structures and methods of the present disclosure may be beneficially applied to manufacturing a semiconductor device such as an integrated circuit. While such examples may be expected to provide various improvements, no particular result is a requirement of the present disclosure unless explicitly recited in a particular claim.

In a flip chip package, a semiconductor die is mounted on a package substrate with its device side surface facing the package substrate. The semiconductor die and the package substrate are covered by a mold compound to protect them from outside environment. An electric field is generated between adjacent metal pads on the semiconductor die and adjacent metal traces on the package substrate. The electric field can stress the mold compound causing reliability concerns, especially for high voltage applications where high performance mold compounds are employed, because due to functional additives in the high performance mold compounds, the high performance mold compounds usually do not provide good electrical insulation. One approach to address such reliability concerns requires large spacing between the metal pads on the semiconductor die and the metal traces on the package substrate. These requirements will increase package size and manufacturing cost. Thus, a flip chip package, which can ease reliability concerns for high performance mold compounds without increasing package size, needs to be developed.

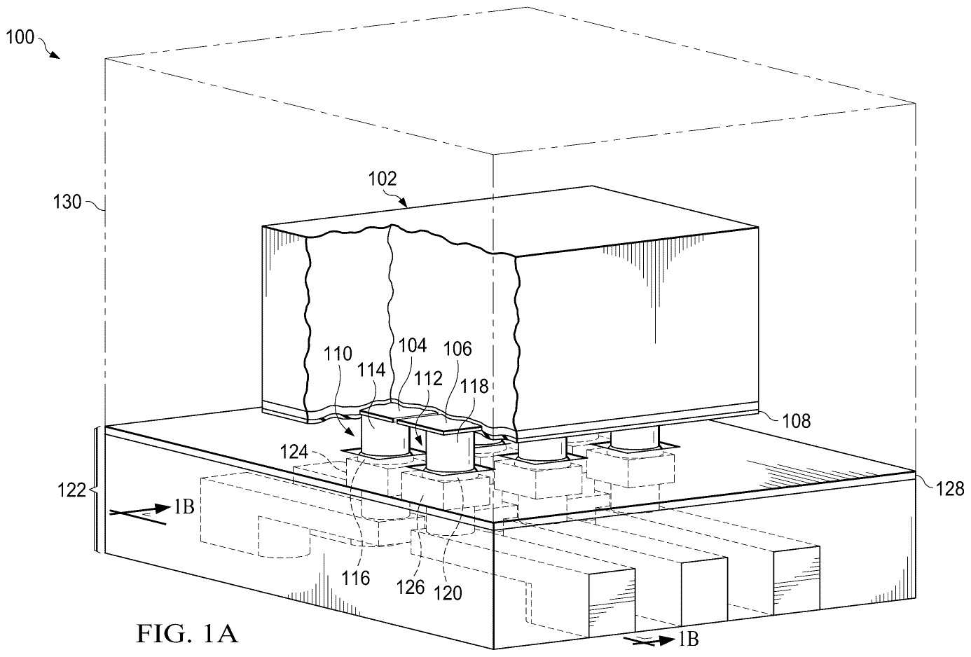

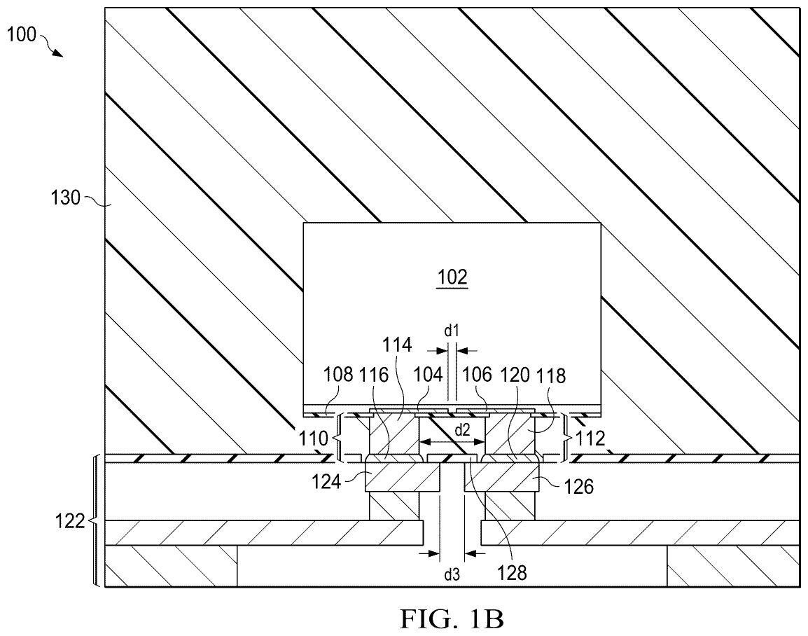

Disclosed aspects include a semiconductor package designed to reduce electric field in high performance mold compound. FIG. 1A is a 3D view of a semiconductor package 100 designed to reduce electric field in high performance mold compound in accordance with certain aspects of present disclosure. FIG. 1B is a cross-section view of the semiconductor package 100 of FIG. 1A along reference line 1B-1B. The semiconductor package 100 comprises a semiconductor die 102. The semiconductor die 102 comprises a first metal pad 104 and a second metal pad 106. The first metal pad 104 and the second metal pad 106 may comprises at least one of copper (Cu) and aluminum (Al). The first metal pad 104 and the second metal pad 106 are separated by a first distance d1. The semiconductor die 102 further comprises a passivation layer 108 in contact with the first metal pad 104 and the second metal pad 106. The passivation layer 108 may comprises at least one of silicon dioxide, silicon nitride, and aluminum oxide. The first distance d1 may be determined based on |V1−V2|/E1, where V1 and V2 are voltages at the first metal pad 104 and the second metal pad 106, respectively, and E1 is breakdown electric field strength of the passivation layer 108. One semiconductor die 102 is shown in FIG. 1A as an example, the semiconductor package 100 may comprise multiple semiconductor dies.

The semiconductor package 100 also comprises a first bump structure 110 and a second bump structure 112. The first bump structure 110 couples to the first metal pad 104 and the second bump structure 112 couples to the second metal pad 106. The first bump structure 110 comprises a first pillar portion 114 and a first solder portion 116. The second bump structure 112 comprises a second pillar portion 118 and a second solder portion 120. The first pillar portion 114 and the second pillar portion 118 may comprise Cu. The first solder portion 116 and the second solder portion 120 may comprise SnAgCu (SAC) solder. The first bump structure 110 and the second bump structure 112 are separated by a second distance d2. In the semiconductor package 100, d1 is smaller than d2.

The semiconductor package 100 also comprises a substrate 122. The substrate 122 comprises a first trace 124 and a second trace 126. The first trace 124 couples to the first bump structure 110 via the first solder portion 116. The second trace 126 couples to the second bump structure 112 via the second solder portion 120. The first trace 124 and the second trace 126 may comprise Cu. The first trace 124 and the second trace 126 are separated by a third distance d3. The substrate 122 further comprises a dielectric layer 128 between the first bump structure 110 and the second bump structure 112 and in contact with the first trace 124 and the second trace 126. The dielectric layer 128 may comprise a solder mask layer. The third distance d3 may be determined based on |V1−V2|/E2, where V1 and V2 are voltages at the first trace 124 and the second trace 126, respectively, and E2 is breakdown electric field strength of the dielectric layer 128.

The semiconductor package 100 further comprises a mold compound 130 covering the semiconductor die 102, the first bump structure 110, the second bump structure 112, and at least a top surface of the substrate 122. The mold compound 130 may comprise high performance mold compound, such as magnetic mold compound and thermally conductive mold compound. The mold compound 130 may also comprise a combination of high performance mold compound and general mold compound. For high performance mold compounds, they usually do not provide good electrical insulation. Thus, there would be reliability concerns when high performance mold compounds are exposed to high electric field. In the semiconductor package 100, high electric fields are confined within the passivation layer 108 when a thickness of the passivation layer 108 is at least one half of the first distance d1. In this case, the mold compound 130 is not affected by electric field generated between the first metal pad 104 and the second metal pad 106. Meanwhile, high electric fields are confined within the dielectric layer 128 when a thickness of the dielectric layer 128 is at least one half of the third distance d3. In this case, the mold compound 130 is not affected by electric field generated between the first trace 124 and the second trace 126. By selecting the thicknesses of the passivation layer 108 and the dielectric layer 128 accordingly, the mold compound 130 is not affected by high electric field. So high performance mold compound could be used in the mold compound 130 to improve performance of the semiconductor package 100 without increasing package size. The semiconductor package 100 is suitable for applications adopting high performance mold compounds.

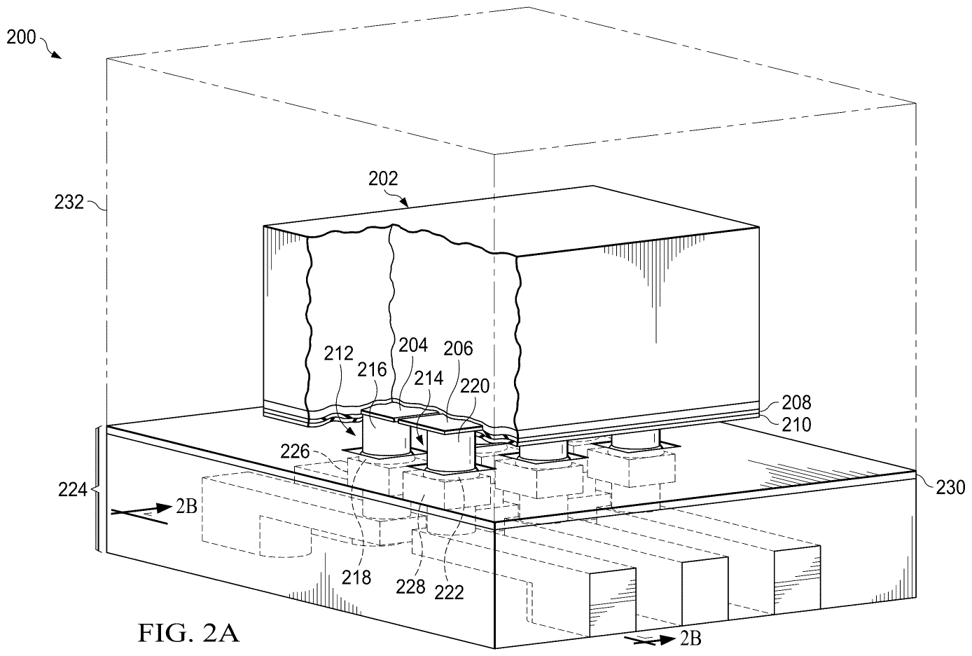

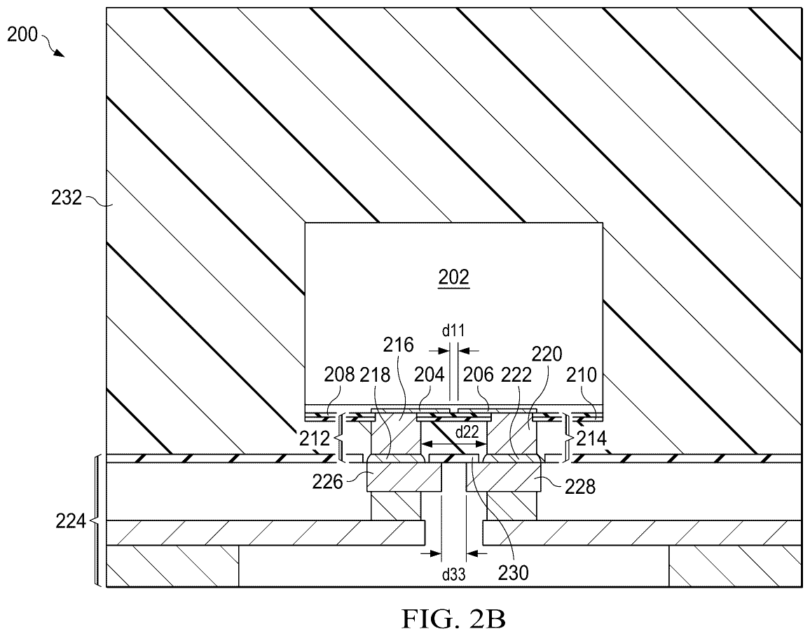

FIG. 2A is a 3D view of a semiconductor package 200 designed to reduce electric field in high performance mold compound in accordance with certain aspects of present disclosure. FIG. 2B is a cross-section view of the semiconductor package 200 of FIG. 2A along reference line 2B-2B. The semiconductor package 200 is similar to the semiconductor package 100. The semiconductor package 200 comprises a semiconductor die 202. The semiconductor die 202 comprises a first metal pad 204 and a second metal pad 206. The first metal pad 204 and the second metal pad 206 may comprises at least one of Cu and Al. The first metal pad 204 and the second metal pad 206 are separated by a first distance d11. The semiconductor die 202 also comprises a passivation layer 208 in contact with the first metal pad 204 and the second metal pad 206. The passivation layer 208 may comprises at least one of silicon dioxide, silicon nitride, and aluminum oxide. The semiconductor die 202 further comprises a first dielectric layer 210 on the passivation layer 208. The first dielectric layer 210 may comprise polyimide (PI). The first distance d11 may be determined based on |V1−V2|/E11, where V1 and V2 are voltages at the first metal pad 204 and the second metal pad 206, respectively, and E11 is breakdown electric field strength of the layer formed by the passivation layer 208 and the first dielectric layer 210. One semiconductor die 202 is shown in FIG. 2A as an example, the semiconductor package 200 may comprise multiple semiconductor dies.

The semiconductor package 200 also comprises a first bump structure 212 and a second bump structure 214. The first bump structure 212 couples to the first metal pad 204 and the second bump structure 214 couples to the second metal pad 206. The first bump structure 212 comprises a first pillar portion 216 and a first solder portion 218. The second bump structure 214 comprises a second pillar portion 220 and a second solder portion 222. The first pillar portion 216 and the second pillar portion 220 may comprise Cu. The first solder portion 218 and the second solder portion 222 may comprise SAC solder. The first bump structure 212 and the second bump structure 214 are separated by a second distance d22. In the semiconductor package 200, d11 is smaller than d22.

The semiconductor package 200 also comprises a substrate 224. The substrate 224 comprises a first trace 226 and a second trace 228. The first trace 226 couples to the first bump structure 212 via the first solder portion 218. The second trace 228 couples to the second bump structure 214 via the second solder portion 222. The first trace 226 and the second trace 228 may comprise Cu. The first trace 226 and the second trace 228 are separated by a third distance d33. The substrate 224 further comprises a second dielectric layer 230 between the first bump structure 212 and the second bump structure 214 and in contact with the first trace 226 and the second trace 228. The second dielectric layer 230 may comprise a solder mask layer. The third distance d33 may be determined based on |V1−V2|/E22, where V1 and V2 are voltages at the first trace 226 and the second trace 228, respectively, and E22 is breakdown electric field strength of the second dielectric layer 230.

The semiconductor package 200 further comprises a mold compound 232 covering the semiconductor die 202, the first bump structure 212, the second bump structure 214, and at least a top surface of the substrate 224. The mold compound 232 may comprise high performance mold compound, such as magnetic mold compound and thermally conductive mold compound. The mold compound 232 may also comprise a combination of high performance mold compound and general mold compound. For high performance mold compounds, they usually do not provide good electrical insulation. Thus, there would be reliability concerns when high performance mold compounds are exposed to high electric field. In the semiconductor package 200, high electric fields are confined within the passivation layer 208 and the first dielectric layer 210 when a thickness of the passivation layer 208 plus the first dielectric layer 210 is at least one half of the first distance d11. In this case, the mold compound 232 is not affected by electric field generated between the first metal pad 204 and the second metal pad 206. Meanwhile, high electric fields are confined within the second dielectric layer 230 when a thickness of the second dielectric layer 230 is at least one half of the third distance d33. In this case, the mold compound 232 is not affected by electric field generated between the first trace 226 and the second trace 228. By selecting the thicknesses of the passivation layer 208, the first dielectric layer 210, and the second dielectric layer 230 accordingly, the mold compound 232 is not affected by high electric field. So high performance mold compound could be used in the mold compound 232 to improve performance of the semiconductor package 200 without increasing package size. The semiconductor package 200 is suitable for applications adopting high performance mold compounds.

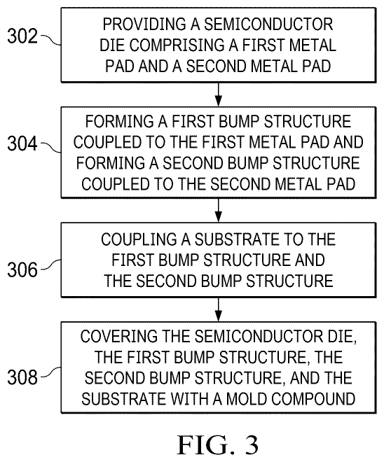

FIG. 3 illustrates a fabrication process for a semiconductor package designed to reduce electric field in high performance mold compound in accordance with certain aspects of present disclosure. Step 302 comprises providing a semiconductor die comprising a first metal pad and a second metal pad. The first metal pad and the second metal pad may comprise at least one of Cu and Al. The first metal pad and the second metal pad are separated by a first distance. The semiconductor die also comprises a passivation layer in contact with the first metal pad and the second metal pad. The passivation layer may comprise at least one of silicon dioxide, silicon nitride, and aluminum oxide. The semiconductor die may further comprise a first dielectric layer on the passivation layer. The first dielectric layer may comprise PI.

Step 304 comprises forming a first bump structure coupled to the first metal pad and forming a second bump structure coupled to the second metal pad. The first bump structure comprises a first pillar portion and a first solder portion. The second bump structure comprises a second pillar portion and a second solder portion. The first pillar portion and the second pillar portion may comprise Cu. The first solder portion and the second solder portion may comprise SAC solder. The first bump structure and the second bump structure are separated by a second distance. In the semiconductor package, the first distance is smaller than the second distance.

Step 306 comprises coupling a substrate to the first bump structure and the second bump structure. The substrate comprises a first trace and a second trace. The first trace couples to the first bump structure via the first solder portion. The second trace couples to the second bump structure via the second solder portion. The first trace and the second trace may comprise Cu. The first trace and the second trace are separated by a third distance. The substrate further comprises a second dielectric layer between the first bump structure and the second bump structure and in contact with the first trace and the second trace. The second dielectric layer may comprise a solder mask layer.

Step 308 comprises covering the semiconductor die, the first bump structure, the second bump structure, and the substrate with a mold compound. The mold compound may comprise high performance mold compound, such as magnetic mold compound and thermally conductive mold compound. The mold compound may also comprise a combination of high performance mold compound and general mold compound. For high performance mold compounds, they usually do not provide good electrical insulation. Thus, there would be reliability concerns when high performance mold compounds are exposed to high electric field. In the semiconductor package, high electric fields are confined within the passivation layer (or the passivation layer plus the first dielectric layer) when a thickness of the passivation layer (or the passivation layer plus the first dielectric layer) is at least one half of the first distance. In this case, the mold compound is not affected by electric field generated between the first metal pad and the second metal pad. Meanwhile, high electric fields are confined within the second dielectric layer when a thickness of the second dielectric layer is at least one half of the third distance. In this case, the mold compound is not affected by electric field generated between the first trace and the second trace. By selecting the thicknesses of the passivation layer, the first dielectric layer, and the second dielectric layer accordingly, the mold compound is not affected by high electric field. So high performance mold compound could be used in the mold compound to improve performance of the semiconductor package without increasing package size. The semiconductor package is suitable for applications adopting high performance mold compounds.

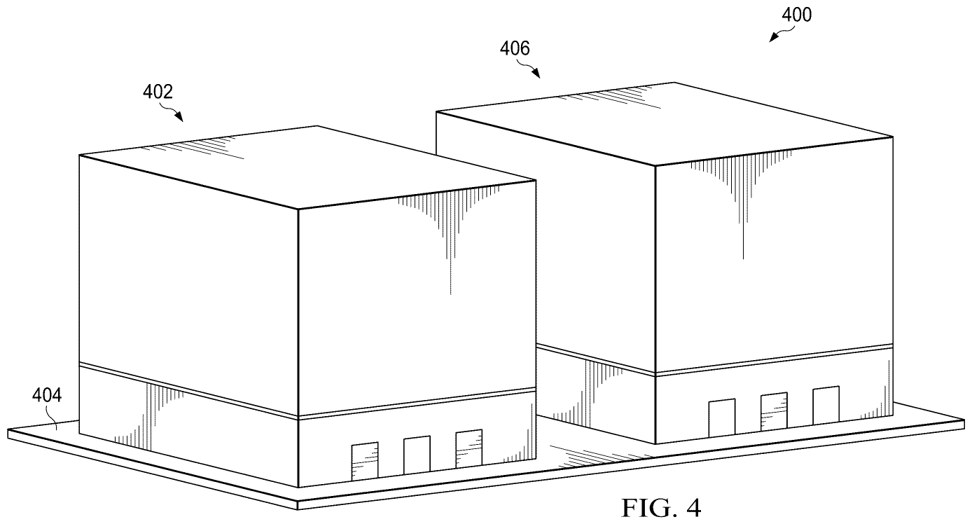

FIG. 4 is a 3D view of a device 400 including a semiconductor package 402 designed to reduce electric field in high performance mold compound in accordance with certain aspects of present disclosure. The device 400 comprises a printed circuit board (PCB) 404. The semiconductor package 402 is mounted on the PCB 404. The semiconductor package 402 is similar to the semiconductor package 100 or the semiconductor package 200 and is suitable for applications adopting high performance mold compounds. The device 400 further comprises another semiconductor package 406 mounted on the PCB 404. The semiconductor packages 402 and 406 operate together to perform functions of the device 400.

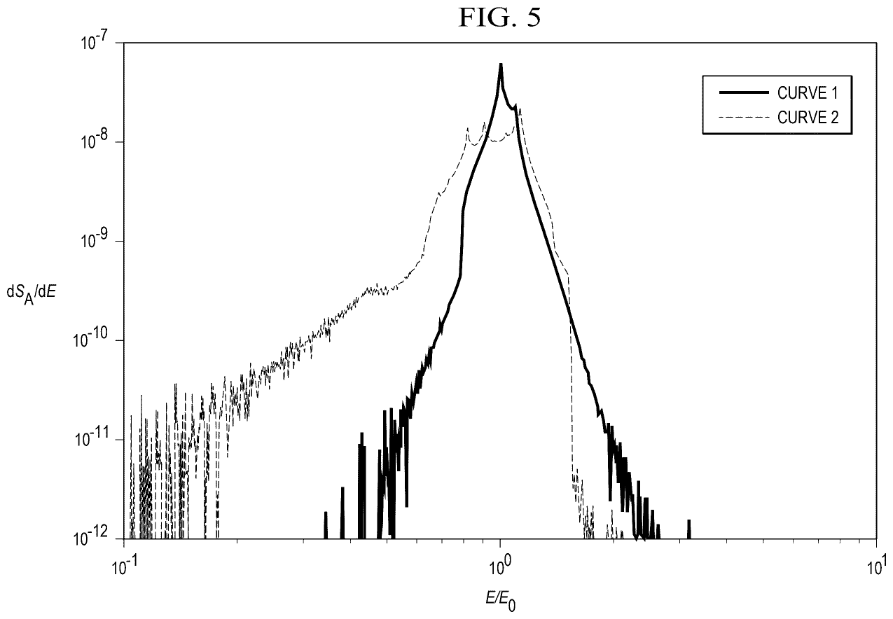

FIG. 5 illustrates simulation results of electric field in mold compound for different semiconductor package designs. Curve 1 represents a semiconductor package in which the first distance d1 is not smaller than the second distance d2 and there is no additional dielectric layer on the substrate. Curve 2 represents a semiconductor package similar to the semiconductor package 100. A maximum electric field for curve 2 is smaller than a maximum electric field for curve 1. Thus, the semiconductor package 100 could reduce electric field in the mold compound and is suitable for applications adopting high performance mold compounds.

Those skilled in the art to which this disclosure relates will appreciate that many variations of disclosed aspects are possible within the scope of the claimed invention, and further additions, deletions, substitutions, and modifications may be made to the above-described aspects without departing from the scope of this disclosure.

What is claimed is:

1. A semiconductor package, comprising:
a semiconductor die, comprising a first metal pad and a second metal pad, the first metal pad separated from the second metal pad by a first distance;
a first bump structure coupled to the first metal pad;
a second bump structure coupled to the second metal pad, wherein the first bump structure is separated from the second bump structure by a second distance;
a substrate, comprising a first trace coupled to the first bump structure and a second trace coupled to the second bump structure; and
a mold compound covering the semiconductor die, the first bump structure, the second bump structure, and the substrate, wherein the first distance is smaller than the second distance.

2. The semiconductor package of claim 1, wherein the substrate comprises a dielectric layer between the first bump structure and the second bump structure and in contact with the first trace and the second trace.

3. The semiconductor package of claim 2, wherein the dielectric layer comprises a solder mask layer.

4. The semiconductor package of claim 2, wherein the dielectric layer has a first thickness, wherein the first trace is separated from the second trace by a third distance, and wherein the first thickness is at least one half of the third distance.

5. The semiconductor package of claim 1, wherein the semiconductor die comprises a passivation layer in contact with the first metal pad and the second metal pad.

6. The semiconductor package of claim 5, wherein the passivation layer has a second thickness and wherein the second thickness is at least one half of the first distance.

7. The semiconductor package of claim 5, wherein the semiconductor die further comprises a polyimide (PI) layer on the passivation layer.

8. The semiconductor package of claim 7, wherein the passivation layer and the PI layer together have a third thickness and wherein the third thickness is at least one half of the first distance.

9. The semiconductor package of claim 1, wherein the mold compound comprises a magnetic mold compound.

10. The semiconductor package of claim 1, wherein the mold compound comprises a thermally conductive mold compound.

11. A method of forming a semiconductor package, comprising:
providing a semiconductor die comprising a first metal pad and a second metal pad, the first metal pad separated from the second metal pad by a first distance;
forming a first bump structure coupled to the first metal pad;
forming a second bump structure coupled to the second metal pad, wherein the first bump structure is separated from the second bump structure by a second distance;
coupling a substrate to the first bump structure and the second bump structure, the substrate comprising a first trace coupled to the first bump structure and a second trace coupled to the second bump structure; and
covering the semiconductor die, the first bump structure, the second bump structure, and the substrate with a mold compound, wherein the first distance is smaller than the second distance.

12. The method of claim 11, further comprising forming a dielectric layer on the substrate in contact with the first trace and the second trace, wherein a portion of the dielectric layer locates between the first bump structure and the second bump structure.

13. The method of claim 12, wherein the dielectric layer has a first thickness, wherein the first trace is separated from the second trace by a third distance, and wherein the first thickness is at least one half of the third distance.

14. The method of claim 11, wherein the semiconductor die comprises a passivation layer in contact with the first metal pad and the second metal pad.

15. The method of claim 14, wherein the passivation layer has a second thickness and wherein the second thickness is at least one half of the first distance.

16. The method of claim 14, wherein the semiconductor die further comprises a polyimide (PI) layer on the passivation layer.

17. The method of claim 16, wherein the passivation layer and the PI layer together have a third thickness and wherein the third thickness is at least one half of the first distance.

18. The method of claim 11, wherein the mold compound comprises a magnetic mold compound.

19. The method of claim 11, wherein the mold compound comprises a thermally conductive mold compound.

20. A device, comprising:
a printed circuit board (PCB); and
a semiconductor package on the PCB, the semiconductor package comprising:
a semiconductor die, comprising a first metal pad and a second metal pad, the first metal pad separated from the second metal pad by a first distance;
a first bump structure coupled to the first metal pad;
a second bump structure coupled to the second metal pad, wherein the first bump structure is separated from the second bump structure by a second distance;
a substrate, comprising a first trace coupled to the first bump structure and a second trace coupled to the second bump structure; and
a mold compound covering the semiconductor die, the first bump structure, the second bump structure, and the substrate, wherein the first distance is smaller than the second distance.
